(19) United States
(12) Patent Application Publication
(10) Pub. No.: US 2021/0327321 A1
(43) Pub. Date: Oct. 21, 2021

(54) SHIFT REGISTER, DRIVING METHOD THEREOF, GATE DRIVING CIRCUIT, AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Hefei, Anhui (CN)

(72) Inventors: Peng CHEN, Beijing (CN); Zixuan WANG, Beijing (CN)

(21) Appl. No.: 16/466,863

(22) PCT Filed: Oct. 31, 2018
(86) PCT No.: PCT/CN2018/112884

§ 371 Date: Jun. 5, 2019

(30) Foreign Application Priority Data
Apr. 17, 2018 (CN) 201810345260.0

(51) Int. Cl. G09G 3/20; G11C 19/28

(52) U.S. Cl. CPC G09G 3/20; G11C 19/28; G09G 2300/0408; G09G 2300/0426; G09G 2310/061; G09G 2310/08; G09G 2330/021; G09G 2310/0286

(57) ABSTRACT

A shift register and a driving method thereof, a grid driving circuit and a display device are disclosed. The shift register includes an input sub-circuit and an output sub-circuit; the input sub-circuit is connected to the signal input terminal and the first node, and is configured to provide signals of the signal input terminal to the first node under the control of the signal input terminal; the output sub-circuit is connected to the first node, the clock signal terminal, the first output terminal and the second output terminal, and is configured to provide signals of the clock signal terminal to the first output terminal and the second output terminal under the control of voltage signals of the first node.

The present application is based on PCT/CN2018/112884, filed on Oct. 31, 2018, and claims priority of the Chinese patent application No. 201810345260.0, filed on Apr. 17, 2018, the disclosure of which is incorporated herein by reference in its entirety as part of the present application.

### TECHNICAL FIELD

The embodiments of the disclosure relate to a shift register and a driving method thereof, a gate driving circuit, and a display device.

### BACKGROUND

In recent years, flat panel displays, such as thin film transistor liquid crystal display (TFT-LCD) and active matrix organic light emitting diode (AMOLED) display panels, have been widely used in electronic products such as televisions and mobile phones due to their advantages of light weight, thin thickness and low power consumption.

With the progress of science and technology, the display panel with high resolution and narrow frame has become the trend of development. Thereby, the Gate Driver on Array (GOA) technology has been proposed. The GOA technology refers to such a technology that GOA circuits for driving gate lines are arranged on both sides or one side of the effective display area of the array substrate in the display panel. A GOA circuit may include, for example, a plurality of shift registers.

### SUMMARY

At least one embodiment of the present disclosure provides a shift register including an input sub-circuit and an output sub-circuit; the input sub-circuit is connected to a signal input terminal and a first node, and is configured to provide signals of the signal input terminal to the first node under the control of the signal input terminal; the output sub-circuit is connected to the first node, the clock signal terminal, a first output terminal and a second output terminal, and is configured to provide signals of the clock signal terminal to the first output terminal and the second output terminal under the control of voltage signals of the first node.

Optionally, the shift register provided in one embodiment of the present disclosure further includes a reset sub-circuit and a noise reduction sub-circuit; the noise reduction sub-circuit is connected to the first node, a first power supply terminal, the first output terminal, the second output terminal and a second power supply terminal, and is configured to provide signals of the second power supply terminal to the first node, the first output terminal and the second output terminal under the control of the first power supply terminal; the reset sub-circuit is connected to the first node, a reset signal terminal, the second power supply terminal and the second output terminal, and is configured to provide signals of the second power supply terminal to the first node and the second output terminal under the control of the reset signal terminal.

Optionally, in the shift register provided by an embodiment of the present disclosure, the input sub-circuit includes a first transistor. A control electrode and a first electrode of the first transistor are connected to the signal input terminal, and a second electrode of the first transistor is connected to the first node.

Optionally, in the shift register provided by an embodiment of the present disclosure, the output sub-circuit includes a second transistor, a third transistor, and a capacitor. A control electrode of the second transistor is connected to the first node, a first electrode of the second transistor is connected to the clock signal terminal, and a second electrode of the second transistor is connected to the first output terminal. A control electrode of the third transistor is connected to the first node, a first electrode of the third transistor is connected to the clock signal terminal, and a second electrode of the third transistor is connected to the second output terminal. A first terminal of the capacitor is connected to the first node, and a second terminal of the capacitor is connected to the first output terminal or the second output terminal.

Optionally, in the shift register provided by an embodiment of the present disclosure, the reset sub-circuit includes a fourth transistor and a fifth transistor. A control electrode of the fourth transistor is connected to the reset signal terminal, a first electrode of the fourth transistor is connected to the first node, and a second electrode of the fourth transistor is connected to the second power supply terminal. A control electrode of the fifth transistor is connected to the reset signal terminal, a first electrode of the fifth transistor is connected to the second output terminal, and a second electrode of the fifth transistor is connected to the second power supply terminal.

Optionally, in the shift register provided by an embodiment of the present disclosure, the noise reduction sub-circuit includes a first noise reduction circuit and a second node control circuit. The first noise reduction circuit is connected to a second node, the first node, the first output terminal, the second output terminal and the second power supply terminal, and is configured to perform noise reduction process on the first node, the first output terminal and the second output terminal under the control of a voltage signal of the second node. The second node control circuit is connected to the first node, the second node and the first power supply terminal, and is configured to control the voltage signal of the second node under the control of a voltage signal of the first node and the first power supply terminal.

Optionally, in the shift register provided by an embodiment of the present disclosure, the first noise reduction circuit includes a seventh transistor, a ninth transistor, and a tenth transistor. The second node control circuit includes a sixth transistor and an eighth transistor. A control electrode of the sixth transistor and a first electrode of the sixth transistor are connected to the first power supply terminal, and a second electrode of the sixth transistor is connected to the second node. A control electrode of the seventh transistor is connected to the second node, a first electrode of the seventh transistor is connected to the first node, and a second electrode of the seventh transistor is connected to the second power supply terminal. A control electrode of the eighth transistor is connected to the first node, a first electrode of the eighth transistor is connected to the second node, and a second electrode of the eighth transistor is connected to the second power supply terminal. A control electrode of the ninth transistor is connected to the second node, a first electrode of the ninth transistor is connected to the first output terminal, and a second electrode of the ninth transistor is connected to the second power supply terminal. A control electrode of the tenth transistor is connected to the second node, a first electrode of the tenth transistor is connected to the second output terminal, and a second electrode of the tenth transistor is connected to the second power supply terminal.

Optionally, the shift register provided in one embodiment of the present disclosure further includes a reset sub-circuit and a noise reduction sub-circuit. The input sub-circuit includes a first transistor; and the output sub-circuit comprises a second transistor, a third transistor and a capacitor. The reset sub-circuit includes a fourth transistor and a fifth transistor. The noise reduction sub-circuit comprises a first noise reduction circuit and a second node control circuit. The first noise reduction circuit comprises a seventh transistor, a ninth transistor and a tenth transistor, and the second node control circuit comprises a sixth transistor and an eighth transistor. A control electrode of the first transistor and a first electrode of the first transistor are connected to the signal input terminal, and a second electrode of the first transistor is connected to the first node. A control electrode of the second transistor is connected to the first node, a first electrode of the second transistor is connected to the clock signal terminal, and a second electrode of the second transistor is connected to the first output terminal. A control electrode of the third transistor is connected to the first node, a first electrode of the third transistor is connected to the clock signal terminal, and a second electrode of the third transistor is connected to the second output terminal. A first terminal of the capacitor is connected to the first node, and a second terminal of the capacitor is connected to the first output terminal or the second output terminal. A control electrode of the fourth transistor is connected to a reset signal terminal, a first electrode of the fourth transistor is connected to the first node, and a second electrode of the fourth transistor is connected to a second power supply terminal. A control electrode of the fifth transistor is connected to the reset signal terminal, a first electrode of the fifth transistor is connected to the second output terminal, and a second electrode of the fifth transistor is connected to the second power supply terminal. A control electrode of the sixth transistor and a first electrode of the sixth transistor are connected to a first power supply terminal, and a second electrode of the sixth transistor is connected to a second node. A control electrode of the seventh transistor is connected to the second node, a first electrode of the seventh transistor is connected to the first node, and a second electrode of the seventh transistor is connected to the second power supply terminal. A control electrode of the eighth transistor is connected to the first node, a first electrode of the eighth transistor is connected to the second node, and a second electrode of the eighth transistor is connected to the second power supply terminal. A control electrode of the ninth transistor is connected to the second node, a first electrode of the ninth transistor is connected to the first output terminal, and a second electrode of the ninth transistor is connected to the second power supply terminal. A control electrode of the tenth transistor is connected to the second node, a first electrode of the tenth transistor is connected to the second output terminal, and a second electrode of the tenth transistor is connected to the second power supply terminal.

Optionally, in the shift register provided by an embodiment of the present disclosure, the first transistor, the second transistor, the third transistor, the fourth transistor, the fifth transistor, the sixth transistor, the seventh transistor, the eighth transistor, the ninth transistor, and the tenth transistor are all P-type thin film transistors. Or, all of the above transistors are N-type thin film transistors.

At least one embodiment of the present disclosure also provides a gate driving circuit, which comprises a plurality of cascaded shift registers; a first output terminal of the N-th stage shift register is connected to signal input terminals of the N+2nd stage shift register and the N+3rd stage shift register, and a first output terminal of the N+3rd stage shift register is connected to reset signal terminals of the N-th stage shift register and the N+1st stage shift register; where n is a positive odd number.

Optionally, the gate driving circuit provided in one embodiment of the present disclosure further comprises a first clock terminal, a second clock terminal, a third clock terminal and a fourth clock terminal. A clock signal terminal of the nth shift register is connected to the first clock terminal, a clock signal terminal of the N+1 shift register is connected to the second clock terminal, a clock signal terminal of the N+2 shift register is connected to the third clock terminal, and a clock signal terminal of the N+3 shift register is connected to the fourth clock terminal.

Optionally, in the gate drive circuit provided by an embodiment of the present disclosure, signals of the first clock terminal, the second clock terminal, the third clock terminal and the fourth clock terminal have the same period and different phases, and the period is equal to 2.5 times of the pulse duration of the signal.

At least one embodiment of the present disclosure also provides a display device including the aforesaid gate driving circuit.

At least one embodiment of the present disclosure also provides a driving method of the shift register, which is applied to the aforesaid shift register. The driving method includes: in an input stage, providing, by the input sub-circuit, the signal of the signal input terminal to the first node under the control of the signal input terminal; in an output stage, providing, by the output sub-circuit, the signal of the clock signal terminal to the first output terminal and the second output terminal under the control of the voltage signal of the first node.

Optionally, the driving method provided in one embodiment of the present disclosure further includes: in a reset stage, providing, by the reset sub-circuit, signals of the second power supply terminal to the first node and the second output terminal under the control of the reset signal terminal, and providing, by the noise reduction sub-circuit, signals of the second power supply terminal to the first node, the first output terminal and the second output terminal under the control of the first power supply terminal.

### BRIEF DESCRIPTION OF THE DRAWINGS

The accompanying drawings are used to provide a further understanding of the technical scheme of the present disclosure and form a part of the specification. Together with the embodiments of the present disclosure, they are used to explain the technical scheme of the present disclosure and do not constitute a limitation on the technical scheme of the present disclosure.

FIG. 1 is a schematic structural diagram of a shift register provided by an embodiment of the disclosure;

FIG. 2 is another schematic structural diagram of a shift register according to an embodiment of the present disclosure.

FIG. 3 is an equivalent circuit diagram of an input sub-circuit of a shift register according to an embodiment of the present disclosure;

FIG. 4 is an equivalent circuit diagram of an output sub-circuit of a shift register according to an embodiment of the present disclosure;

FIG. 5 is an equivalent circuit diagram of a reset sub-circuit of a shift register according to an embodiment of the present disclosure;

FIG. 6 is an equivalent circuit diagram of a noise reduction sub-circuit of a shift register according to an embodiment of the present disclosure;

FIG. 7 is an equivalent circuit diagram of a shift register provided by an embodiment of the present disclosure;

FIG. 8 is an operation timing diagram of the shift register provided by the embodiment of the disclosure;

FIG. 9 is a flowchart of a method for driving a shift register according to an embodiment of the present disclosure;

FIG. 10 is a schematic structural diagram of a gate drive circuit according to an embodiment of the present disclosure;

FIG. 11 is an operation timing diagram of a gate driving circuit provided in an embodiment of the disclosure;

FIG. 12 is a schematic diagram of a display device provided by an embodiment of the disclosure.

### DETAILED DESCRIPTION

In order to make the objects, technical schemes and advantages of the present disclosure more clear, embodiments of the present disclosure will be described in detail below with reference to the accompanying drawings. It should be noted that the embodiments in this application and the features in the embodiments can be combined in any way as long as they do not conflict with each other.

The steps shown in the flowcharts may be performed in a computer system such as a set of computer executable instruction. Also, although a logical sequence is shown in the flowchart, in some cases, the steps shown or described may be performed in a sequence different from that herein.

Unless otherwise defined, technical terms or scientific terms used in the disclosure of the embodiments of the disclosure shall have the common meaning understood by those having ordinary skills in the art to which the disclosure belongs. The words “first”, “second” and the like used in the embodiments of the present disclosure do not indicate any sequence, quantity or importance, but are only used to distinguish different components. Similar words such as “include” or “comprise” always refer to the element or error detection in front of the word to cover the element or item listed after the word and its equivalent, and do not exclude other elements or items. Similar words such as “connected” or “coupled” are not limited to physical or mechanical connections, but may include electrical connections, which may be direct or indirect.

Those skilled in the art can understand that the transistors used in all embodiments of this application can be thin film transistors or field effect transistors or other devices with the same characteristics. For example, the thin film transistors used in the embodiment of the present disclosure may be oxide semiconductor transistors. Since the source and drain electrodes of the transistor used in the present disclosure are symmetrical, the source and drain electrodes can be interchanged. In the embodiment of the present disclosure, in order to distinguish the two electrodes of the transistor except the gate electrode, one of the source and drain electrodes is referred to as the first electrode and the other electrode is referred to as the second electrode, the first electrode may be the source or drain, the second electrode may be the drain or source, and in addition, the gate of the transistor is referred to as the control electrode.

According to the research of the inventor of the application, the transistor for outputting a gate drive signal in a common GOA circuit usually has a large size, so that the power consumption of a shift register is large, and thereby the working stability and using reliability are reduced and display effects of a display panel are affected.

The output terminal of a normal GOA circuit not only provides a gate drive signal for a gate line connected to a shift register of the current stage, but also provides a cascade signal for a lower shift register as an input signal of the lower shift register. For example, a cascade signal may be provided for a shift register connected to the lower shift register as a reset signal, so that the transistor for outputting the gate drive signal has a larger size and the power consumption of the shift register is larger, thereby reducing the working stability, use reliability and affecting display effect of the display panel.

In order to solve the above technical problems, the embodiment of the present disclosure provides a shift register, a driving method thereof, a gate driving circuit, and a display device, which can reduce the power consumption of the shift register and improve the working stability, use reliability, and display effects of a display panel.

Of course, the implementation of any product or method of the present disclosure need not necessarily achieve all of the advantages described above at the same time. Other features and advantages of the present disclosure will be set forth in the following description embodiments, and in part will be apparent from the description embodiments, or may be learned by practicing the present disclosure. The objects and other advantages of the embodiments of the present disclosure can be realized and attained by the structures particularly pointed out in the specification, claims and drawings.

The embodiment of the disclosure provides a shift register and a driving method thereof, a gate driving circuit and a display device. The shift register includes an input sub-circuit and an output sub-circuit. The input sub-circuit is connected to the signal input terminal and the first node and is configured to provide signals of the signal input terminal to the first node under the control of the signal input terminal. The output sub-circuit is connected to the first node, the clock signal terminal, the first output terminal and the second output terminal, and is configured to provide signals of the clock signal terminal to the first output terminal and the second output terminal under the control of voltage signals of the first node. According to the embodiment of the disclosure, two output terminals are arranged, one output terminal is configured to output a gate driving signal to a gate line connected to the shift register of the current stage, and the other output terminal is configured to output a cascade signal as an input signal or a reset signal of the shift register of other stages, so that the size of a transistor for outputting signals is reduced, the power consumption of the shift register is reduced, and the working stability, the use reliability and the display effect of the display panel are improved.

The shift register and its driving method, gate driving circuit, and display device provided by the embodiment of the present disclosure are specifically described as follows.

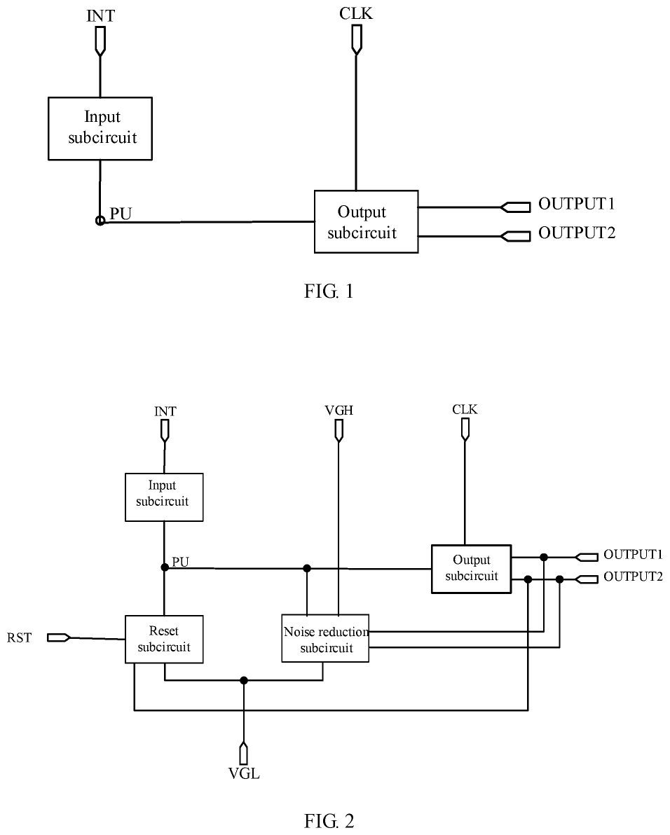

FIG. 1 is a schematic structural diagram of a shift register provided by an embodiment of the present disclosure. As shown in FIG. 1, the shift register provided by the embodiment of the present disclosure includes an input sub-circuit and an output sub-circuit.

For example, the input sub-circuit is connected to the signal input terminal INT and a first node (e.g., the pull-up node PU) for providing a signal of the signal input terminal INT to the pull-up node PU under the control of the signal input terminal INT. The output sub-circuit is connected to the pull-up node PU, the clock signal terminal CLK, the first output terminal OUTPUT1 and the second output terminal OUTPUT2, and is configured to provide signals of the clock signal terminal CLK to the first output terminal OUTPUT1 and the second output terminal OUTPUT2 under the control of the pull-up node PU. Here, the pull-up node PU is an example of the first node. In the following description, the pull-up node PU is referred to as the first node, but this does not constitute a limitation to the embodiment of the present disclosure.

For example, the first output terminal OUTPUT1 is connected to signal inputs of other stage shift registers (e.g., lower two stage shift registers and lower three stage shift registers) cascaded with the stage shift register as input signals of the other stage shift registers, or is connected to reset signal terminals of other stage shift registers (e.g., upper two stage shift registers and upper three stage shift registers) cascaded with the stage shift register as reset signal of the other stage shift registers; the second output terminal OUTPUT2 provides a gate drive signal for the gate line connected to the shift register of this stage.

For example, the signal input terminal INT inputs a pulse signal, the first output terminal OUTPUT1 and the second output terminal OUTPUT2 outputs a pulse signal, the signal of the clock signal terminal CLK is a periodic signal (for example, a clock signal), and the period thereof is equal to 2.5 times of the pulse duration of the periodic signal.

The shift register provided by the embodiment of the disclosure comprises an input sub-circuit and an output sub-circuit. The input sub-circuit is connected to the signal input terminal and the first node and is configured to provide signals of the signal input terminal to the first node under the control of the signal input terminal. The output sub-circuit is connected to the first node, the clock signal terminal, the first output terminal and the second output terminal, and is configured to provide signals of the clock signal terminal to the first output terminal and the second output terminal under the control of voltage signals of the first node. According to the embodiment of the disclosure, two output terminals (i.e., a first output terminal and a second output terminal) are arranged, one output terminal (e.g., a second output terminal) is configured to output a gate drive signal to a gate line connected to the shift register of the current stage, and the other output terminal (e.g., the first output terminal) is configured to output a cascade signal as an input signal or a reset signal of the shift register of other stages, so that the size of a transistor for outputting the signal is reduced, the power consumption of the shift register is reduced, and the working stability, use reliability and display effects of the display panel are improved.

Optionally, FIG. 2 is a schematic structural diagram 2 of the shift register provided by the embodiment of the present disclosure. As shown in FIG. 2, the shift register provided by the embodiment of the present disclosure further includes a reset sub-circuit and a noise reduction sub-circuit.

For example, the noise reduction sub-circuit is connected to the pull-up node PU, the first power supply terminal VGH, the first output terminal OUTPUT1, the second output terminal OUTPUT2 and the second power supply terminal VGL, and is configured to provide signals of the second power supply terminal VOL to the pull-up node PU, the first output terminal OUTPUT1 and the second output terminal OUTPUT2 under the control of the first power supply terminal VGH. The reset sub-circuit is connected to the pull-up node PU, the reset signal terminal RST, the second power supply terminal VGL and the second output terminal OUTPUT2, and is configured to provide signals of the second power supply terminal VGL to the pull-up node PU and the second output terminal OUTPUT2 under the control of the reset signal terminal RST.

For example, the first power supply terminal VGH continuously provides DC high level signal, and the second power supply terminal VOL continuously provides a DC low level signal (e.g., ground).

According to the embodiment of the present disclosure, by adding a noise reduction sub-circuit and a reset sub-circuit to the shift register, the noise of the shift register (for example, the noise of the first output terminal OUTPUT1 and the second output terminal OUTPUT2) can be reduced and reset can be realized, thus further improving the working stability, use reliability and display effect of the display panel.

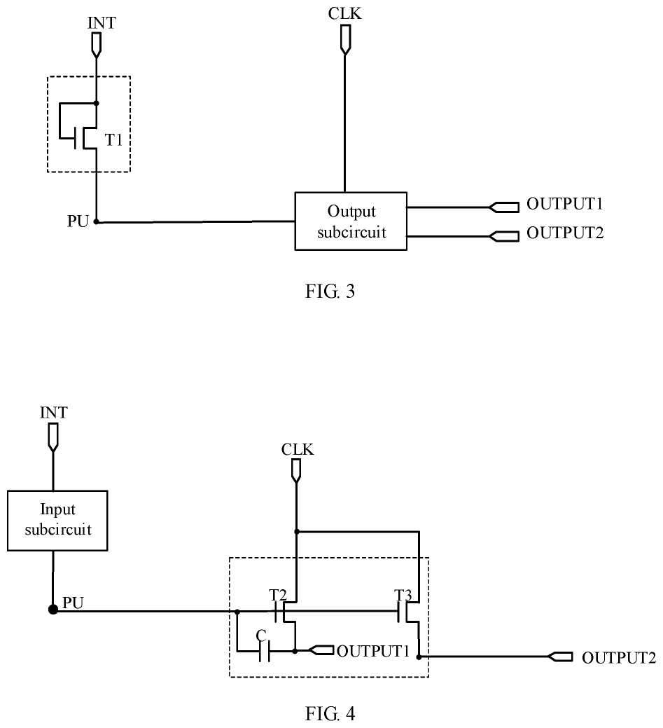

Optionally, FIG. 3 shows an equivalent circuit diagram of the input sub-circuit of the shift register provided by the embodiment of the disclosure. as shown in FIG. 3, the input sub-circuit of the shift register provided by the embodiment of the disclosure includes: a first transistor t1; the control electrode of the first transistor T1 and the first electrode of the first transistor T1 are connected to the signal input terminal INT, and the second electrode of the first transistor T1 is connected to the pull-up node PU.

In this embodiment, an exemplary structure of the input sub-circuit is specifically shown in FIG. 3. Those skilled in that art will readily understand that the implementation of the input sub-circuit is not limited to this, as long as its function can be realized.

Optionally, FIG. 4 shows an equivalent circuit diagram of the output sub-circuit of the shift register provided by the embodiment of the disclosure. As shown in FIG. 4, the output sub-circuit of the shift register provided by the embodiment of the disclosure includes a second transistor T2, a third transistor T3 and a capacitor c. The control electrode of the second transistor T2 is connected to the pull-up node PU, the first electrode of the second transistor T2 is connected to the clock signal terminal CLK, and the second electrode of the second transistor T2 is connected to the first output terminal OUTPUT1. The control electrode of the third transistor T3 is connected to the pull-up node PU, the first electrode of the third transistor T3 is connected to the clock signal terminal CLK, and the second electrode of the third transistor T3 is connected to the second output terminal OUTPUT2. The first terminal of the capacitor C is connected to the pull-up node PU, and the second terminal of the capacitor C is connected to the first output terminal OUTPUT1. For example, in another example, the second terminal of the capacitor C may also be connected to the second output terminal OUTPUT2, and the embodiment of the present disclosure is not limited to this.

For example, the capacitance C may be a liquid crystal capacitance composed of a pixel electrode and a common electrode, or may be an equivalent capacitance composed of a liquid crystal capacitance composed of a pixel electrode and a common electrode and a storage capacitance. For example, the capacitor C may be a capacitor device manufactured by a process, for example, a special capacitor electrode is manufactured to realize the capacitor device, each electrode of the capacitor may be realized by a metal layer, a semiconductor layer (e.g., doped polysilicon), etc., and the capacitor C may also be a parasitic capacitor between each device, and may be realized by the transistor itself, other devices, and circuits, which are not limited by the embodiments of the present disclosure.

For example, the second transistor T2 and the third transistor T3 in the output sub-circuit provided by the embodiment of the present disclosure are configured to provide a cascade signal and a gate drive signal respectively, so the channels of the second transistor T2 and the third transistor T3 are relatively small, and the power consumption of the shift register is saved.

In this embodiment, an exemplary structure of the output sub-circuit is specifically shown in FIG. 4. Those skilled in that art will readily understand that the implementation of the output sub-circuit is not limited to this, as long as its function can be realized.

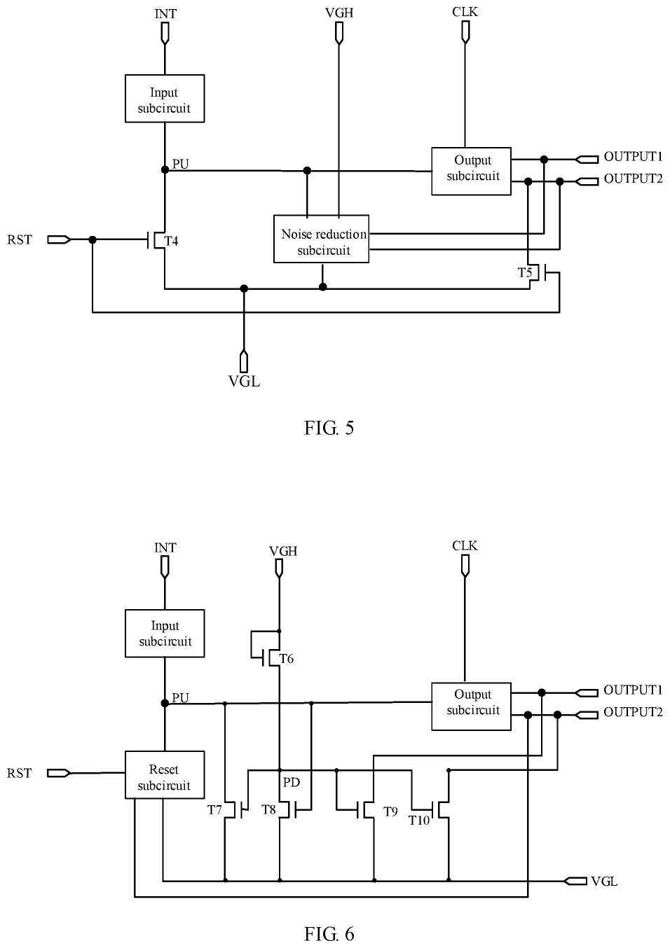

Optionally, FIG. 5 is the equivalent circuit diagram of the reset sub-circuit of the shift register provided by the embodiment of the disclosure. As shown in FIG. 5, the reset sub-circuit of the shift register provided by the embodiment of the disclosure includes a fourth transistor T4 and a fifth transistor t5. The control electrode of the fourth transistor T4 is connected to the reset signal terminal RST, the first electrode of the fourth transistor T4 is connected to the pull-up node PU, and the second electrode of the fourth transistor T4 is connected to the second power supply terminal VGL The control electrode of the fifth transistor T5 is connected to the reset signal terminal RST, the first electrode of the fifth transistor T5 is connected to the second output terminal OUTPUT2, and the second electrode of the fifth transistor T5 is connected to the second power supply terminal VGL.

In this embodiment, an exemplary structure of the reset sub-circuit is specifically shown in FIG. 5. Those skilled in that art will readily understand that the implementation of the reset sub-circuit is not limited to this, as long as its function can be realized.

Optionally, FIG. 6 is the equivalent circuit diagram of the noise reduction sub-circuit of the shift register provided by the embodiment of the disclosure, as shown in FIG. 6, the noise reduction sub-circuit of the shift register provided by the embodiment of the disclosure includes a first noise reduction circuit and a second node control circuit. The first noise reduction circuit is connected to a second node (e.g., pull-down node PD), a pull-up node PU, a first output terminal OUTPUT1, a second output terminal OUTPUT2, and a second power supply terminal VGL. The first noise reduction circuit is configured to perform noise reduction on the pull-up node PU, the first output terminal OUTPUT1, and the second output terminal OUTPUT2 under the control of a voltage signal of the pull-down node PD. The second node control circuit is connected to the pull-up node PU, the pull-down node PD and the first power supply terminal VGH, and is configured to control the voltage signal of the pull-down node PD under the control of the voltage signal of the pull-up node PU and the first power supply terminal VGH. Here, the pull-down node PD is an example of the second node, and in the following description, the pull-down node PD is all described as an example of the second node, but this does not constitute a limitation to the embodiment of the present disclosure.

For example, the first noise reduction circuit includes a seventh transistor T7, a ninth transistor T9, and a tenth transistor T10; and the second node control circuit includes a sixth transistor T6 and an eighth transistor T8. The control electrode of the sixth transistor T6 and the first electrode of the sixth transistor T6 are connected to the first power supply terminal VGH, and the second electrode of the sixth transistor T6 is connected to the pull-down node PD. The control electrode of the seventh transistor T7 is connected to the pull-down node PD, the first electrode of the seventh transistor T7 is connected to the pull-up node PU, and the second electrode of the seventh transistor T7 is connected to the second power supply terminal VGL. The control electrode of the eighth transistor T8 is connected to the pull-up node PU, the first electrode of the eighth transistor T8 is connected to the pull-down node PD, and the second electrode of the eighth transistor T8 is connected to the second power supply terminal VGL. The control electrode of the ninth transistor T9 is connected to the pull-down node PD, the first electrode of the ninth transistor T9 is connected to the first output terminal OUTPUT1, and the second electrode of the ninth transistor T9 is connected to the second power supply terminal VGL. The control electrode of the tenth transistor T10 is connected to the pull-down node PD, the first electrode of the tenth transistor T10 is connected to the second output terminal OUTPUT2, and the second electrode of the tenth transistor T10 is connected to the second power supply terminal VGL.

In this embodiment, an exemplary structure of the noise reduction sub-circuit is specifically shown in FIG. 6. Those skilled in that art will readily understand that the implementation of the noise reduction sub-circuit is not limited to this, as long as its function can be realized.

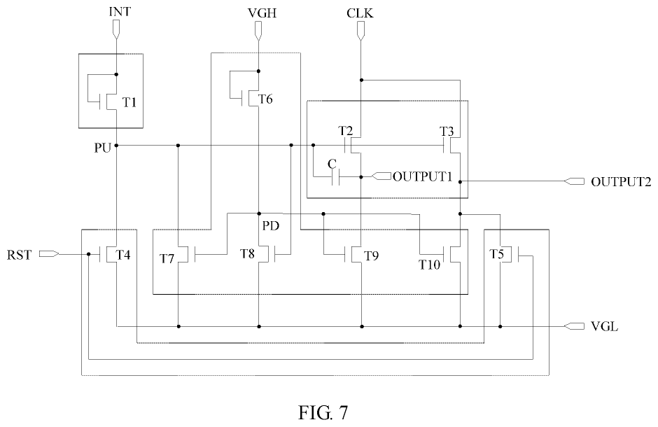

Optionally, FIG. 7 is an equivalent circuit diagram of a shift register provided by an embodiment of the disclosure, the shift register provided by the embodiment of the disclosure includes an input sub-circuit, an output sub-circuit, a reset sub-circuit and a noise reduction sub-circuit. The noise reduction sub-circuit includes a first noise reduction circuit and a second node control circuit. The input sub-circuit includes a first transistor T1; the output sub-circuit includes a second transistor T2, a third transistor T3 and a capacitor C; the reset sub-circuit includes a fourth transistor T4 and a fifth transistor T5; the first noise reduction circuit includes a seventh transistor 17, a ninth transistor T9, and a tenth transistor T10; and the second node control circuit includes a sixth transistor T6 and an eighth transistor T8.

For example, the control electrode of the first transistor T1 and the first electrode of the first transistor T1 are connected to the signal input terminal INT, and the second electrode of the first transistor T1 is connected to the pull-up node PU; the control electrode of the second transistor T2 is connected to the pull-up node PU, the first electrode of the second transistor T2 is connected to the clock signal terminal CLK, and the second electrode of the second transistor T2 is connected to the first output terminal OUTPUT1. The control electrode of the third transistor T3 is connected to the pull-up node PU, the first electrode of the third transistor T3 is connected to the clock signal terminal CLK, and the second electrode of the third transistor T3 is connected to the second output terminal OUTPUT2. The first terminal of the capacitor C is connected to the pull-up node PU, and the second terminal of the capacitor C is connected to the first output terminal OUTPUT1. The control electrode of the fourth transistor T4 is connected to the reset signal terminal RST, the first electrode of the fourth transistor T4 is connected to the pull-up node PU, and the second electrode of the fourth transistor T4 is connected to the second power supply terminal VGL. The control electrode of the fifth transistor T5 is connected to the reset signal terminal RST, the first electrode of the fifth transistor T5 is connected to the second output terminal OUTPUT2, and the second electrode of the fifth transistor T5 is connected to the second power supply terminal VGL. The control electrode of the sixth transistor T6 and the first electrode of the sixth transistor T6 are connected to the first power supply terminal VGH, and the second electrode of the sixth transistor T6 is connected to the pull-down node PD. The control electrode of the seventh transistor T7 is connected to the pull-down node PD, the first electrode of the seventh transistor T7 is connected to the pull-up node PU, and the second electrode of the seventh transistor T7 is connected to the second power supply terminal VGL. The control electrode of the eighth transistor T8 is connected to the pull-up node PU, the first electrode of the eighth transistor T8 is connected to the pull-down node PD, and the second electrode of the eighth transistor T8 is connected to the second power supply terminal VGL. The control electrode of the ninth transistor T9 is connected to the pull-down node PD, the first electrode of the ninth transistor T9 is connected to the first output terminal OUTPUT1, and the second electrode of the ninth transistor 19 is connected to the second power supply terminal VGL. The control electrode of the tenth transistor T10 is connected to the pull-down node PD, the first electrode of the tenth transistor T10 is connected to the second output terminal OUTPUT2, and the second electrode of the tenth transistor T10 is connected to the second power supply terminal VGL.

Exemplary structures of an input sub-circuit, an output sub-circuit, a reset sub-circuit and a noise reduction sub-circuit are specifically shown in this embodiment. Those skilled in that art will readily understand that the implementation of the above sub-circuits is not limit to this, as long as their respective functions can be realized.

In this embodiment, transistors T1 to T10 can all be N-type thin film transistors, or all of them are P-type thin film transistors, which can unify the process flow, reduce the process flow, and help to improve the yield of products. Of course, the embodiment of the present disclosure is not limited to this, and some transistors may adopt N-type thin film transistors and other transistors may adopt P-type thin film transistors. After determining the type of transistor, it is only necessary to connect each electrode of the transistor of the selected type with reference to each electrode of the corresponding transistor in the embodiment of the present disclosure, and make the corresponding power supply terminal provide the corresponding high voltage or low voltage. When N-type transistors are used, Indium Gallium Zinc Oxide (IGZO) can be used as the active layer of the thin film transistor. Compared with low temperature poly-silicon (LTPS) or amorphous silicon (such as hydrogenated amorphous silicon) as the active layer of the thin film transistor, the size of the transistor can be effectively reduced and leakage current can be prevented. The thin film transistor may be a thin film transistor with a bottom gate structure or a thin film transistor with a top gate structure as long as the switching function can be realized, and the embodiment of the present disclosure is not limited to this.

It should be noted that in the description of various embodiments of the present disclosure, the first node, the second node, the pull-up node PU and the pull-down node PD do not represent actual components, but rather represent the junction points of related electrical connections in the circuit diagram.

The technical solution of the disclosed embodiment will be described further with reference to the working process of the shift register hereinafter.

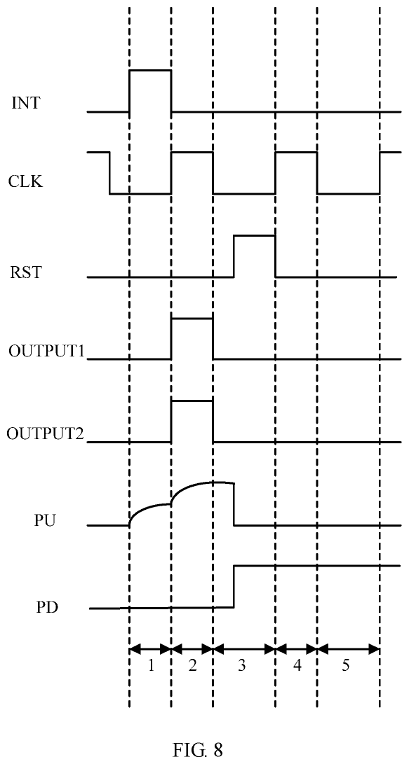

Taking that all the transistors T1 to T10 in the shift register provided by the embodiment of the present disclosure are N-type thin film transistors as an example, FIG. 8 is an operation timing diagram of the shift register provided by the embodiment of the present disclosure. As shown in FIG. 7 and FIG. 8, the shift register provided by the embodiment of the present disclosure includes ten (10) transistors (T1 to T10), one (1) capacitor (C), three (3) signal input terminals (INT, RST and CLK), two (2) signal output terminals (OUTPUT1 and OUTPUT2) and two (2) power supply terminals (VGH and VOL). Reference symbols TNT, CLK, RST, OUTPUT1, OUTPUT2, PU, PD, and etc. are used to represent both corresponding signal terminals or nodes and corresponding signals. This apply to the following embodiments, and will not be described again.

For example, the first power supply terminal VGH continuously provides DC high level signal; and the second power supply terminal VOL continuously provides a DC low level signal (e.g., ground signal).

In the first stage 1, that is, the input stage, the signal at the signal input terminal INT is at a high level, and the first transistor T1 is turned on to pull up the potential of the pull-up node PU and charge the capacitor C. The second transistor T2 and the third transistor T3 are turned on under the control of the pull-up node PU to output signals of the clock signal terminal CLK to the first output terminal OUTPUT1 and the second output terminal OUTPUT2, respectively.

In this stage, the input signal of the signal input terminal INT is at a high level, the input signals of the reset signal terminal RST and the clock signal terminal CLK are at low levels, and the output signals of the first output terminal OUTPUT1 and the second output terminal OUTPUT2 are at low levels. Although the first power supply terminal VGH continues to provide a high level signal and the sixth transistor T6 remains on, the potential of the pull-up node PU will not be pulled down. This is because, the eighth transistor T8 is turned on due to the high potential of the pull-up node PU, and the potential of the pull-down node PD is lowered due to the voltage dividing effect of the sixth transistor T6 and the eighth transistor T8 (e.g., by designing the channel aspect ratio of the sixth transistor T6 and the eighth transistor T8). Thus, the seventh transistor T7, the ninth transistor T9 and the tenth transistor T10 are not turned on (i.e., remains off), and therefore the potential of the pull-up node PU will not be pulled down.

In the second Stage 2, that is, the output stage, the signal of the signal input terminal INT is at a low level, the first transistor T1 is turned off, and the signal of the clock signal terminal CLK becomes a high level. Due to the bootstrap effect of the capacitor C, the potential of the pull-up node PU continues to be pulled high, the high level of the pull-up node PU enables the second transistor T2 and the third transistor T3 to be fully turned on, and the first output terminal OUTPUT1 outputs the high level signal of the clock signal terminal CLK, as a cascade signal. The second output terminal OUTPUT2 outputs a high level signal of the clock signal terminal CLK to provide a gate driving signal to a gate connected to the second output terminal OUTPUT2. In addition, the increase of the potential of the pull-up node PU improves the conduction capability of the second transistor T2 and the third transistor T3, and ensures the potential of the output signals of the first output terminal OUTPUT1 and the second output terminal OUTPUT2, thus facilitates charging the corresponding pixel units.

In this stage, the input signal of the clock signal terminal CLK is at a high level, the input signals of the signal input terminal INT and the reset signal terminal RST are at low levels, the output signal of the first output terminal OUTPUT1 is at a high level, and the output signal of the second output terminal OUTPUT2 is at a high level. Since the potential of the pull-up node PU is still at a high level, the eighth transistor T8 is still on, which pulls down the potential of the pull-down node PD. The seventh transistor T7, the ninth transistor T9, and the tenth transistor T10 are not turned on, and the potentials of the pull-up node PU, the first output terminal OUTPUT1, and the second output terminal OUTPUT2 are not pulled down.

In the third stage 3, that is, the reset stage, the input signal of the reset signal terminal RST is at a high level, the fourth transistor T4 is turned on, the potential of the pull-up node PU is pulled down to a low level of the second power supply terminal VOL, the fifth transistor T5 is turned on, and the potential of the second output terminal OUTPUT2 is pulled down to a low level of the second power supply terminal VGL, thereby realizing reset. Since the potential of the pull-up node PU is low, the eighth transistor T8 is turned off, the potential of the pull-down node PD becomes high under the action of the sixth transistor T6, the seventh transistor 17 is turned on, the potential of the pull-up node PU is continuously pulled down to reduce noise, the ninth transistor T9 is turned on, the potential of the first output terminal OUTPUT1 is pulled down to the low level of the second power supply terminal VOL, the tenth transistor T10 is turned on, and the potential of the second output terminal OUTPUT2 is continuously pulled down to reduce noise.

It should be noted that the input signal of the reset signal terminal RST changes to a high level after 1/3 period of this stage. The input signal of the reset signal terminal RST is still at a low level in the previous 1/3 period, the potential of the pull-up node PU is at a high level in the previous 1/3 period, the eighth transistor T8 is turned on, the potential of the pull-down node PD is still at a low level in the previous 1/3 period, and the output signals of the first output terminal OUTPUT1 and the second output terminal OUTPUT2 are at a low level because the input signal of the clock signal terminal CLK is at a low level in the previous 1/3 period.

In this stage, the input signal of the reset signal RST is at a high level, the input signals of the signal input terminal INT and the clock signal terminal CLK are at a low level, the output signal of the first output terminal OUTPUT1 is at a low level, and the output signal of the second output terminal OUTPUT2 is at a low level.

In the fourth stage 4, the input signal of the clock signal terminal CLK is at a high level. Since the potential of the pull-up node PU is at a low level, the second transistor T2 and the third transistor T3 are turned off, the output signals of the first output terminal OUTPUT1 and the second output terminal OUTPUT2 are at a low level. Meanwhile, the eighth transistor T8 is turned off, the potential of the pull-down node PD is at a high level, the seventh transistor T7 is turned on, and the potential of the pull-up node PU is continuously pulled down to reduce noise. The ninth transistor T9 is turned on, the potential of the first output terminal OUTPUT1 is continuously pulled low, the tenth transistor T10 is turned on, and the potential of the second output terminal OUTPUT2 is continuously pulled low to reduce noise.

In this stage, the input signal of the clock signal terminal CLK is at a high level, the input signals of the signal input terminal INT and the reset signal terminal RST are at low levels, the output signal of the first output terminal OUTPUT1 is at a low level, and the output signal of the second output terminal OUTPUT2 is at a low level.

In the fifth stage 5, the input signal of the clock signal terminal CLK is at a low level. Since the potential of the pull-up node PU is at a low level, the second transistor T2 and the third transistor T3 are turned off, the output signals of the first output terminal OUTPUT1 and the second output terminal OUTPUT2 are at low levels. Meanwhile, the eighth transistor T8 is turned off, the potential of the pull-down node PD is at a high level, the seventh transistor T7 is turned on, and the potential of the pull-up node PU is continuously pulled down to reduce noise. The ninth transistor T9 is turned on, the potential of the first output terminal OUTPUT1 is continuously pulled low, the tenth transistor T10 is turned on, and the potential of the second output terminal OUTPUT2 is continuously pulled low to reduce noise.

In this stage, the input signals of the clock signal terminal CLK, the signal input terminal INT and the reset signal terminal RST are at low levels, the output signal of the first output terminal OUTPUT1 is at a low level, and the output signal of the second output terminal OUTPUT2 is at a low level.

After the reset stage 3, the shift register of this stage continues the fourth stage 4 and the fifth stage 5 until the signal input INT receives the high level signal again.

In this embodiment, the signal at the signal input terminal INT is a pulse signal and is high only at the input stage. The output signal of the first output terminal OUTPUT1 is a pulse signal and is at a high level only in the output stage. The output signal of the second output terminal OUTPUT2 is a pulse signal and is at a high level only in the output stage. The signal of RST at the reset signal terminal is a pulse signal and is at a high level only in the reset phase.

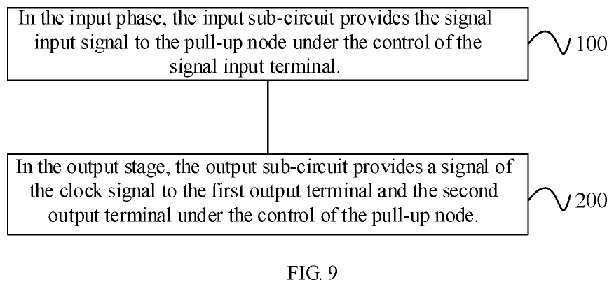

Based on the inventive concept of the above embodiment, the embodiment of the present disclosure also provides a driving method of the shift register, which is applied to the shift register provided by the above embodiment. FIG. 9 is a flowchart of a driving method of a shift register provided by the embodiment of the disclosure. The shift register includes a signal input terminal INT, a reset signal terminal RST, a clock signal terminal CLK, a first output terminal OUTPUT1, a second output terminal OUTPUT2, a first power supply terminal VGH and a second power supply terminal VGL, an input sub-circuit, an output sub-circuit, a reset sub-circuit and a noise reduction sub-circuit. As shown in FIG. 9, the driving method of the shift register provided by the embodiment of the disclosure includes the following steps.

Step 100: In the input stage, the input sub-circuit provides the signal of the signal input terminal to the first node (e.g., pull-up node) under the control of the signal input terminal.

For example, the input signal at the signal input terminal is a pulse signal, and in step 100, the input sub-circuit pulls up or lowers the potential of the first node.

Step 200: In the output stage, the output sub-circuit provides signals at the clock signal terminals to the first output terminal and the second output terminal under the control of voltage signals at the first node (e.g., pull-up node).

For example, the first output terminal OUTPUT1 is connected to the signal input terminals INT of the lower two-stage shift register and the lower three-stage shift register, or is connected to the reset signal terminal RST of the upper two-stage shift register and the upper three-stage shift register; and the second output terminal OUTPUT2 provides a gate drive signal for the gate line connected to the shift register of this stage.

For example, the first output terminal OUTPUT1 and the second output terminal OUTPUT2 output pulse signals, the signal of the clock signal terminal CLK is a periodic signal (for example, a clock signal), and the period is equal to 2.5 times of the pulse duration.

The driving method of the shift register provided by the embodiment of the disclosure comprises the following steps: in an input stage, an input sub-circuit provides a signal of a signal input terminal to a first node under the control of the signal input terminal; in the output stage, the output sub-circuit provides signals at the clock signal terminal to the first output terminal and the second output terminal under the control of the voltage signal at the first node. According to the embodiment of the disclosure, by arranging two output terminals (i.e., a first output terminal and a second output terminal), one output terminal (e.g., a second output terminal) for outputting a gate drive signal to a gate line which is connected to a shift register of the current stage, and the other output terminal (e.g., the first output terminal) for outputting a cascade signal, the size of a transistor for outputting the signal is reduced, the power consumption of the shift register is reduced, and the working stability, the use reliability and the display effect of the display panel are improved.

Optionally, the driving method of the shift register provided by the embodiment of the present disclosure further comprises: in the reset stage, the reset sub-circuit provides signals of the second power supply terminal to the first node (e.g., pull-up node) and the second output terminal under the control of the reset signal terminal, and the noise reduction sub-circuit provides signals of the second power supply terminal to the first node (e.g., pull-up node), the first output terminal and the second output terminal under the control of voltage signals of the first power supply terminal and the first node (e.g., pull-up node).

For example, the signal at the reset signal terminal is a pulse signal, and the reset sub-circuit pulls down the potentials of the first node, the first output terminal and the second output terminal to reset and avoid noise.

For example, the transistors in the shift register provided by the embodiment of the present disclosure are all N-type thin film transistors, the input signal of the first power supply terminal is at a high level, and the input signal of the second power supply terminal is at a low level. In the input stage, the signal at the signal input terminal is at a high level. In the output stage, the output signals of the first output terminal and the second output terminal are at high levels. In the reset phase, the signal at the reset signal terminal is at a high level.

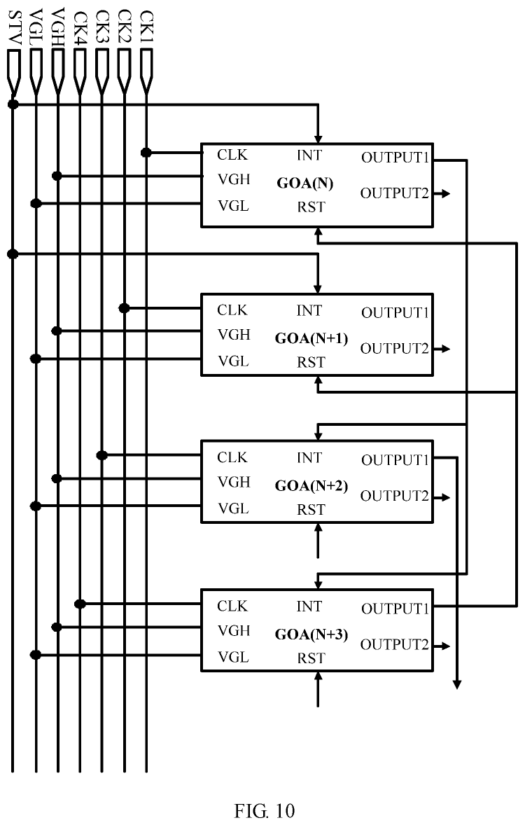

Based on the inventive concept of the above embodiment, the embodiment of the present disclosure also provides a gate drive circuit. FIG. 10 is a schematic structural diagram of the gate drive circuit provided in the embodiment of the present disclosure. As shown in FIG. 10, the gate drive circuit provided in the embodiment of the present disclosure includes a plurality of cascaded shift registers, which are the shift registers described in any of the above embodiments.

For example, the first output terminal OUTPUT1 of the shift register of the N-th stage is connected to the signal input terminal INT of the shift register of the N+2nd stage and the shift register of the N+3rd stage, and the first output terminal OUTPUT1 of the shift register of the N+3rd stage is connected to the reset signal terminal RST of the shift register of the N-th stage and the shift register of the N+1st stage.

It should be noted that N is a positive odd number. That is, the first output terminal OUTPUT1 of the first stage shift register is connected to the signal input terminals INT of the third stage shift register and the fourth stage shift register, and the first output terminal OUTPUT1 of the fourth stage shift register is connected to the reset signal terminal RST of the first stage shift register and the second stage shift register. The first output terminal OUTPUT1 of the third-stage shift register is connected to the signal input terminals INT of the fifth-stage shift register and the sixth-stage shift register, and the first output terminal OUTPUT1 of the sixth-stage shift register is connected to the reset signal terminals RST of the third-stage shift register and the fourth-stage shift register, and so on.

For example, the signal input terminals INT of the first stage shift register and the second stage shift register are connected to the initial signal terminal STV. For example, the reset signal terminal RST of the last two-stage shift register is connected to a reset signal line separately provided.

Further, the first output terminal OUTPUT1 of the N+3rd stage shift register is only connected to the reset signal terminal RST of the N+1st stage shift register and the N+3rd stage shift register. The first output terminal OUTPUT1 of the N-th stage shift register is connected only to the signal input terminals INT of the N+2nd stage shift register and the N+3rd stage shift register, that is, the first output terminals OUTPUT1 of the 1st, 3rd, 5th, . . . stage shift register are connected only to the corresponding subsequent shift register, while the first output terminals OUTPUT1 of the 4th, 6th, 8th, . . . stage shift register is connected only to the corresponding preceding shift register. Therefore, the first output terminal OUTPUT1 of each odd-level shift register supplies signals only to the signal input terminal INT of the corresponding lower-level shift register, and the first output terminal OUTPUT1 of each even-level shift register supplies signals only to the reset signal terminal RST of the corresponding upper-level shift register.

Optionally, as shown in FIG. 10, the gate driving circuit provided by the embodiment of the present disclosure further includes a first clock terminal CK1, a second clock terminal CK2, a third clock terminal CK3, and a fourth clock terminal CK4.

For example, the clock signal terminal CLK of the N-th shift register is connected to the first clock terminal CK1, the clock signal terminal CLK of the N+1st shift register is connected to the second clock terminal CK2, the clock signal terminal CLK of the N+2nd shift register is connected to the third clock terminal CK3, and the clock signal terminal CLK of the N+3rd shift register is connected to the fourth clock terminal CK4, and so on.

In this embodiment, the clock signal terminal CLK of the first stage shift register is connected to the first clock terminal CK1, the clock signal terminal CLK of the second stage shift register is connected to the second clock terminal CK2, the clock signal terminal CLK of the third stage shift register is connected to the third clock terminal CK3, and the clock signal terminal CLK of the fourth stage shift register is connected to the fourth clock terminal CK4. The clock signal terminal CLK of the fifth-stage shift register is connected to the first clock terminal CK1, the clock signal terminal CLK of the sixth-stage shift register is connected to the second clock terminal CK2, the clock signal terminal CLK of the seventh-stage shift register is connected to the third clock terminal CK3, and the clock signal terminal CLK of the eighth-stage shift register is connected to the fourth clock terminal CK4. Every four-stage of shift registers is one cycle, and so on.

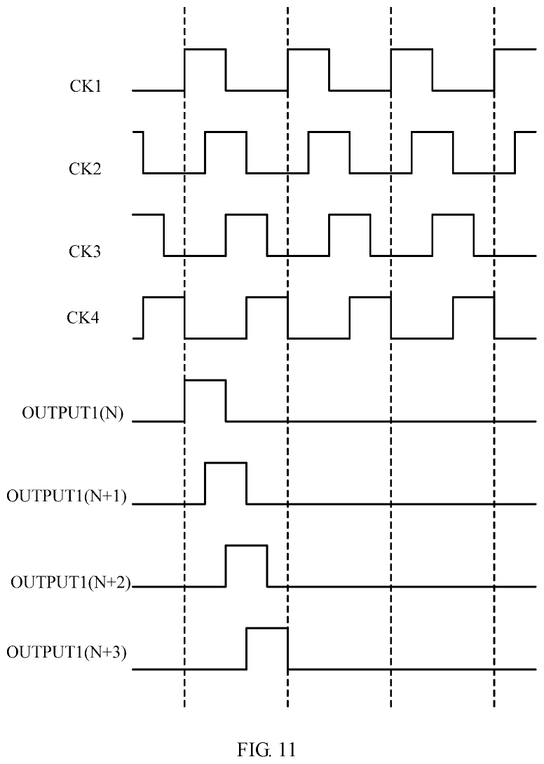

FIG. 11 is an operation timing diagram of the gate drive circuit provided in the embodiment of the disclosure. As shown in FIG. 11, the signals of the first clock terminal CK1, the second clock terminal CK2, the third clock terminal CK3, and the fourth clock terminal CK4 have the same period and different phases, and the period is equal to 2.5 times of the signal pulse duration. Of course, the embodiment of the present disclosure is not limited to this, and the period of the signal at each clock terminal may be other multiples of the pulse duration. The phases of the signals at each clock terminal are sequentially delayed.

The output signal of the first output terminal OUTPUT1 of the shift register of the N-th stage is OUTPUT1(N), the output signal of the first output terminal OUTPUT1 of the shift register of the N+1st stage is OUTPUT1(N+1), the output signal of the first output terminal OUTPUT1 of the shift register of the N+2nd stage is OUTPUT1(N+2), and the output signal of the first output terminal OUTPUT1 of the shift register of the N+3rd stage is OUTPUT1(N+3). The output signal of the second output terminal OUTPUT2 is the same as that of the corresponding first output terminal OUTPUT1, and is not shown in the figure. Therefore, the gate driving circuit can output shift signals to a plurality of gate lines connected thereto as gate driving signals.

According to the cascade mode of the gate drive circuit provided by the embodiment of the disclosure, the number of cascade circuits is reduced, the layout space is reduced, and the narrow frame of the display panel is facilitated to be realized.

The shift register in the gate drive circuit is the shift register provided in the above embodiment, and its implementation principle and effect are similar, so it will not be repeated here.

Based on the inventive concept of the above embodiment, the embodiment of the present disclosure also provides a display device including a gate driving circuit.

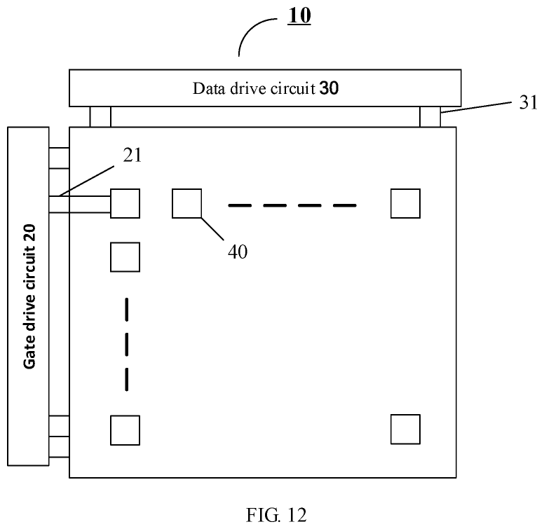

As shown in FIG. 12, the display device 10 provided by the embodiment of the present disclosure includes a gate driving circuit 20. The display device 10 further includes a pixel array composed of a plurality of pixel unite 40. For example, the display device 10 may further include a data driving circuit 30. The data driving circuit 30 is configured to provide data signals for the pixel array; and the gate drive circuit 20 is configured to provide a gate drive signal for the pixel array. The data driving circuit 30 is electrically connected to the pixel unit 40 by the data line 31, and the gate driving circuit 20, which may be implemented as GOA, for example, is directly prepared on the array substrate of the display device 10, and is electrically connected to the pixel unit 40 by the gate line 21.

The gate drive circuit 20 is the gate drive circuit provided in the above embodiment, and its implementation principle and effect are similar, so it will not be repeated here.

For example, the display device 10 may be any product or component having a display function, such as, an OLED panel, an LCD panel, a mobile phone, a tablet computer, a television, a display, a notebook computer, a digital photo frame, a navigator, etc.

The following statements should be noted:

(1) The accompanying drawings illustrate only the structure(s) involved in the embodiment(s) of the present disclosure, and other structure(s) can be referred to common design(s).

(2) Features in one embodiment or in different embodiments can be combined as long as they do not conflict with each other.

Although the disclosed embodiments of the present disclosure have been described above, the above description is only an embodiment for facilitating understanding of the present disclosure and is not intended to limit the present disclosure. Any person skilled in the art to which this disclosure belongs may make any modifications and changes in the form and details of implementation without departing from the scope of this disclosure, but the scope of patent protection of this disclosure shall still be subject to the scope defined in the appended claims.

1. A shift register comprising:
an input sub-circuit, connected to a signal input terminal and a first node, and the input sub-circuit being configured to provide signals of the signal input terminal to the first node under control of the signal input terminal; and
an output sub-circuit, connected to the first node, the clock signal terminal, a first output terminal and a second output terminal, and the output sub-circuit being configured to provide signals of the clock signal terminal to the first output terminal and the second output terminal under control of voltage signals of the first node.

2. The shift register according to claim 1, further comprising:
a noise reduction sub-circuit, connected to the first node, a first power supply terminal, the first output terminal, the second output terminal and a second power supply terminal, and the noise reduction sub-circuit being configured to provide signals of the second power supply terminal to the first node, the first output terminal and the second output terminal under control of the first power supply terminal; and
a reset sub-circuit, connected to the first node, a reset signal terminal, the second power supply terminal and the second output terminal, and the reset sub-circuit being configured to provide signals of the second power supply terminal to the first node and the second output terminal under control of the reset signal terminal.

3. The shift register according to claim 1, wherein the input sub-circuit comprises:
a first transistor, a control electrode of the first transistor and a first electrode of the first transistor being connected to the signal input terminal, and the second electrode of the first transistor being connected to the first node.

4. The shift register according to claim 1, wherein the output sub-circuit comprises a second transistor, a third transistor and a capacitor;
the control electrode of the second transistor is connected to the first node, the first electrode of the second transistor is connected to the clock signal terminal, and the second electrode of the second transistor is connected to the first output terminal;
the control electrode of the third transistor is connected to the first node, the first electrode of the third transistor is connected to the clock signal terminal, and the second electrode of the third transistor is connected to the second output terminal;
the first terminal of the capacitor is connected to the first node, and the second terminal of the capacitor is connected to the first output terminal or the second output terminal.

5. The shift register according to claim 2, wherein the reset sub-circuit comprises:
a fourth transistor, a control electrode of the fourth transistor being connected to the reset signal terminal, a first electrode of the fourth transistor being connected to the first node, and a second electrode of the fourth transistor being connected to the second power supply terminal; and
a fifth transistor, a control electrode of the fifth transistor being connected to the reset signal terminal, a first electrode of the fifth transistor being connected to the second output terminal, and a second electrode of the fifth transistor being connected to the second power supply terminal.

6. The shift register according to claim 2, wherein the noise reduction sub-circuit comprises:
a first noise reduction circuit, connected to a second node, the first node, the first output terminal, the second output terminal and the second power supply terminal, and the first noise reduction circuit being configured to perform noise reduction process on the first node, the first output terminal and the second output terminal under control of a voltage signal of the second node; and
a second node control circuit, connected to the first node, the second node and the first power supply terminal, and the second node control circuit being configured to control the voltage signal of the second node under control of a voltage signal of the first node and the first power supply terminal.

7. The shift register according to claim 6, wherein the first noise reduction circuit comprises:
a seventh transistor, a control electrode of the seventh transistor being connected to the second node, a first electrode of the seventh transistor being connected to the first node, and a second electrode of the seventh transistor being connected to the second power supply terminal;
a ninth transistor, a control electrode of the ninth transistor being connected to the second node, a first electrode of the ninth transistor being connected to the first output terminal, and a second electrode of the ninth transistor being connected to the second power supply terminal; and
a tenth transistor, a control electrode of the tenth transistor being connected to the second node, a first electrode of the tenth transistor being connected to the second output terminal, and a second electrode of the tenth transistor being connected to the second power supply terminal; and
wherein the second node control circuit comprises:
a sixth transistor, a control electrode of the sixth transistor and a first electrode of the sixth transistor being connected to the first power supply terminal, and a second electrode of the sixth transistor being connected to the second node; and
an eighth transistor, a control electrode of the eighth transistor being connected to the first node, a first electrode of the eighth transistor being connected to the second node, and a second electrode of the eighth transistor being connected to the second power supply terminal.

8. The shift register according to claim 1, further comprising:
a reset sub-circuit, which comprises a fourth transistor and a fifth transistor; and
a noise reduction sub-circuit, which comprises a first noise reduction circuit and a second node control circuit, wherein the first noise reduction circuit comprises a seventh transistor, a ninth transistor and a tenth transistor, and the second node control circuit comprises a sixth transistor and an eighth transistor; and
wherein the input sub-circuit comprises a first transistor; and the output sub-circuit comprises a second transistor, a third transistor and a capacitor; and
wherein:
a control electrode of the first transistor and a first electrode of the first transistor are connected to the signal input terminal, and a second electrode of the first transistor is connected to the first node;
a control electrode of the second transistor is connected to the first node, a first electrode of the second transistor is connected to the clock signal terminal, and a second electrode of the second transistor is connected to the first output terminal;
a control electrode of the third transistor is connected to the first node, a first electrode of the third transistor is connected to the clock signal terminal, and a second electrode of the third transistor is connected to the second output terminal;
a first terminal of the capacitor is connected to the first node, and a second terminal of the capacitor is connected to the first output terminal or the second output terminal;
a control electrode of the fourth transistor is connected to a reset signal terminal, a first electrode of the fourth transistor is connected to the first node, and a second electrode of the fourth transistor is connected to a second power supply terminal;
a control electrode of the fifth transistor is connected to the reset signal terminal, a first electrode of the fifth transistor is connected to the second output terminal, and a second electrode of the fifth transistor is connected to the second power supply terminal;
a control electrode of the sixth transistor and a first electrode of the sixth transistor are connected to a first power supply terminal, and a second electrode of the sixth transistor is connected to a second node;
a control electrode of the seventh transistor is connected to the second node, a first electrode of the seventh transistor is connected to the first node, and a second electrode of the seventh transistor is connected to the second power supply terminal;
a control electrode of the eighth transistor is connected to the first node, a first electrode of the eighth transistor is connected to the second node, and a second electrode of the eighth transistor is connected to the second power supply terminal;
a control electrode of the ninth transistor is connected to the second node, a first electrode of the ninth transistor is connected to the first output terminal, and a second electrode of the ninth transistor is connected to the second power supply terminal;
a control electrode of the tenth transistor is connected to the second node, a first electrode of the tenth transistor is connected to the second output terminal, and a second electrode of the tenth transistor is connected to the second power supply terminal.

9. The shift register according to claim 8, wherein all of the first transistor, the second transistor, the third transistor, the fourth transistor, the fifth transistor, the sixth transistor, the seventh transistor, the eighth transistor, the ninth transistor, and the tenth transistor are P-type thin film transistors, or, all of them are N-type thin film transistors.

10. A gate drive circuit comprising a plurality of cascaded shift registers according to claim 1, wherein,
a first output terminal of an N-th shift register is connected to signal input terminals of an N+2nd shift register and an N+3rd shift register, and a first output terminal of the N+3rd shift register is connected to reset signal terminals of the N-th shift register and an N+1st shift register;
where N is a positive odd number.

11. The gate driving circuit according to claim 10, further comprising a first clock terminal, a second clock terminal, a third clock terminal and a fourth clock terminal, wherein
a clock signal terminal of the N-th shift register is connected to the first clock terminal, a clock signal terminal of the N+1st shift register is connected to the second clock terminal, a clock signal terminal of the N+2nd shift register is connected to the third clock terminal, and a clock signal terminal of the N+3rd shift register is connected to the fourth clock terminal.

12. The gate driving circuit according to claim 11, wherein signals of the first clock terminal, the second clock terminal, the third clock terminal and the fourth clock terminal have a same period and different phases, and the period is equal to 2.5 times of the pulse duration of the signal.

13. A display device comprising the gate driving circuit according to claim 10.

14. A driving method of a shift register applied to the shift register according to claim 1, the driving method comprising:
in an input stage, providing, by the input sub-circuit, the signal of the signal input terminal to the first node under the control of the signal input terminal;
in an output stage, providing, by the output sub-circuit, the signal of the clock signal terminal to the first output terminal and the second output terminal under the control of the voltage signal of the first node.

15. The driving method according to claim 14, further comprising:
in a reset phase, providing, by a reset sub-circuit, signals of the second power supply terminal to the first node and the second output terminal under the control of the reset signal terminal, and providing, by a noise reduction sub-circuit, signals of the second power supply terminal to the first node, the first output terminal and the second output terminal under the control of the first power supply terminal.

16. The shift register according to claim 2, wherein the input sub-circuit comprises:
a first transistor, a control electrode of the first transistor and a first electrode of the first transistor being connected to the signal input terminal, and the second electrode of the first transistor being connected to the first node.

17. The shift register according to claim 2, wherein the output sub-circuit comprises a second transistor, a third transistor and a capacitor;
the control electrode of the second transistor is connected to the first node, the first electrode of the second transistor is connected to the clock signal terminal, and the second electrode of the second transistor is connected to the first output terminal;
the control electrode of the third transistor is connected to the first node, the first electrode of the third transistor is connected to the clock signal terminal, and the second electrode of the third transistor is connected to the second output terminal;
the first terminal of the capacitor is connected to the first node, and the second terminal of the capacitor is connected to the first output terminal or the second output terminal.

18. The shift register according to claim 3, wherein the output sub-circuit comprises a second transistor, a third transistor and a capacitor;
the control electrode of the second transistor is connected to the first node, the first electrode of the second transistor is connected to the clock signal terminal, and the second electrode of the second transistor is connected to the first output terminal;
the control electrode of the third transistor is connected to the first node, the first electrode of the third transistor is connected to the clock signal terminal, and the second electrode of the third transistor is connected to the second output terminal;
the first terminal of the capacitor is connected to the first node, and the second terminal of the capacitor is connected to the first output terminal or the second output terminal.

19. The shift register according to claim 5, wherein the noise reduction sub-circuit comprises:
a first noise reduction circuit, connected to a second node, the first node, the first output terminal, the second output terminal and the second power supply terminal, and the first noise reduction circuit being configured to perform noise reduction process on the first node, the first output terminal and the second output terminal under control of a voltage signal of the second node; and
a second node control circuit, connected to the first node, the second node and the first power supply terminal, and the second node control circuit being configured to control the voltage signal of the second node under control of a voltage signal of the first node and the first power supply terminal.

20. The shift register according to claim 19, wherein the first noise reduction circuit comprises:
a seventh transistor, a control electrode of the seventh transistor being connected to the second node, a first electrode of the seventh transistor being connected to the first node, and a second electrode of the seventh transistor being connected to the second power supply terminal;
a ninth transistor, a control electrode of the ninth transistor being connected to the second node, a first electrode of the ninth transistor being connected to the first output terminal, and a second electrode of the ninth transistor being connected to the second power supply terminal; and
a tenth transistor, a control electrode of the tenth transistor being connected to the second node, a first electrode of the tenth transistor being connected to the second output terminal, and a second electrode of the tenth transistor being connected to the second power supply terminal; and
wherein the second node control circuit comprises:
a sixth transistor, a control electrode of the sixth transistor and a first electrode of the sixth transistor being connected to the first power supply terminal, and a second electrode of the sixth transistor being connected to the second node; and
an eighth transistor, a control electrode of the eighth transistor being connected to the first node, a first electrode of the eighth transistor being connected to the second node, and a second electrode of the eighth transistor being connected to the second power supply terminal.
